(19) United States
(12) Patent Application Publication
(10) Pub. No.: US 2015/0062811 A1
(43) Pub. Date: Mar. 5, 2015

(54) ELECTRIC POWER CONVERSION DEVICE FOR VEHICLE AND RAILWAY VEHICLE

(71) Applicant: KABUSHIKI KAISHA TOSHIBA, Tokyo (JP)

(72) Inventors: Hiroomi SUZUKI, Saitama (JP); Hiroaki YOSHINARI, Tokyo (JP)

(73) Assignee: KABUSHIKI KAISHA TOSHIBA, Tokyo (JP)

(21) Appl. No.: 14/181,424

(22) Filed: Feb. 14, 2014

(30) Foreign Application Priority Data
Aug. 30, 2013 (JP) 2013-179843

(51) Int. Cl. H05K 7/20; B61C 3/00

(52) U.S. Cl. CPC H05K 7/209; B61C 3/00; H05K 7/2089; H05K 2007/20527
USPC 361/690

(57) ABSTRACT

An electric power conversion device for a vehicle includes a box body partitioned into a cooling air chamber and a mounting chamber, a heat generation part which is arranged in the inside of the mounting chamber and includes a semiconductor element which performs power conversion, and a heat radiation part mounted on a partition between the cooling air chamber and mounting chamber, and configured to radiate heat generated from the heat generation part, wherein the heat generation part is detachably mounted on the heat radiation part in a state where the heat generation part is arranged on a side opposite to the heat radiation part with the partition sandwiched therebetween, and a heat transfer sheet is provided between the heat generation part and the heat radiation part.

### CROSS-REFERENCE TO RELATED APPLICATION

This application is based upon and claims the benefit of priority from Japanese Patent Application No. 2013-179843, filed Aug. 30, 2013, the entire contents of which are incorporated herein by reference.

### FIELD

Embodiments described herein relate generally to an electric power conversion device for a vehicle, and a railway vehicle.

### BACKGROUND

With respect to a railway vehicle, in general, as a device for performing a control of a main motor for driving (operating to move and control) the railway vehicle or the like, an electric power conversion device for a vehicle is mounted on an underfloor of a vehicle body, for example.

Conventionally, an electric power conversion device for a vehicle includes a control box which is mounted on an underfloor of a vehicle body and defines a sealed space in the inside thereof, a power unit part accommodated in the inside of the control box (a unit which performs power conversion by making use of a switching operation of a semiconductor element), and a heat removing part which is mounted on the control box in a state where the heat removing part is opened to the outside of the control box and radiates, convects (with adjacent air) and conducts heat generated from the power unit part into adjacent materials, including ambient air. A packing is interposed between the power unit part and the heat removing part thus maintaining the sealed state in the inside of the control box.

However, the electric power conversion device for a vehicle of the related art has a structure which uses such a packing and hence, the structure as a whole is liable to become complicated. Further, the heat removing part largely projects outwardly compared to the control box and hence, it is necessary to pay attention to an outfitting space which is set in advance, i.e., a space for placement of the power conversion device which is predefined or dictated as a design constraint of the device and the railway vehicle. In view of the above, there has been known a method where a semiconductor element which is liable to generate a large amount of heat is directly mounted on a control box by way of a heat receiving plate so that heat may be efficiently removed therefrom by making use of a heat conducting, convecting and radiating area of the control box thus performing cooling of the semiconductor element.

However, even when the heat receiving plate is directly mounted on the control box, it is difficult to bring both parts into close contact with each other due to unevenness, deflection or the like of surfaces of these parts and hence, a gap is liable to be formed between both parts. Since heat resistance is increased due to such a gap, heat generated from a semiconductor element may not be efficiently transferred to the control box through the heat receiving plate. Accordingly, it is difficult to perform cooling of the semiconductor element by sufficiently making use of a heat removing area of the control box.

Further, there may be a case where the heat removing part which includes fins or the like is integrally formed on the heat receiving plate. In this case, the heat receiving plate on which the semiconductor element is mounted is directly mounted on the control box together with the heat removing part. Accordingly, when the semiconductor element is removed from the control box for maintenance or the like, for example, it is necessary to remove not only the heat receiving plate but also the heat removing part simultaneously and hence, there is a room for enhancement in the ease of mounting or removing the semiconductor element.

### DESCRIPTION OF THE DRAWINGS

FIG. 1 is a view showing a railway vehicle according to a first embodiment.

FIG. 2 is a constitutional view of an electric power conversion device for a vehicle shown in FIG. 1, and is also a perspective view of the electric power conversion device for a vehicle as viewed from a left side of the railway vehicle.

FIG. 3 is a perspective view showing a cooling air chamber and an area around the cooling air chamber shown in FIG. 2 in an enlarged manner.

FIG. 4 is an exploded perspective view showing a state where a power unit shown in FIG. 3 is mounted on partition plates.

FIG. 5 is a cross-sectional view taken along a line A-A in FIG. 3.

FIG. 6 is a cross-sectional view taken along a line B-B in FIG. 3.

FIG. 7 is a view showing a modification of the first embodiment, and is also an exploded perspective view showing a state before a power unit is mounted on partition plates.

FIG. 8 is a perspective view of an electric power conversion device for a vehicle of a second embodiment as viewed from a left side of a railway vehicle.

FIG. 9 is a cross-sectional view taken along a line C-C in FIG. 8.

FIG. 10 is a perspective view of an electric power conversion device for a vehicle of a third embodiment as viewed from a left side of a railway vehicle.

### DETAILED DESCRIPTION

According to an embodiment, there is provided an electric power conversion device for a vehicle which may enhance cooling performance by efficiently transferring heat generated from a heat generation part to a heat radiation part and, at the same time, may enhance the ease of mounting or removing the heat generation part.

In general, according to one embodiment, an electric power conversion device for a vehicle includes: a box body partitioned into a cooling air chamber and amounting chamber; a heat generation part which is arranged in the inside of the mounting chamber and includes a semiconductor element which performs power conversion; and a heat removing part mounted on a partition between the cooling air chamber and mounting chamber, and configured to transfer heat generated from the heat generation part, wherein the heat generation part is attachably and detachably mounted on the heat removing part in a state where the heat generation part is arranged on a side opposite to the heat removing part with the partition sandwiched therebetween, and a heat transfer sheet is provided between the heat generation part and the heat removing part.

A railway vehicle of the embodiment includes: the electric power conversion device for a vehicle; and a vehicle body where the box body is mounted on an underfloor.

Hereinafter, embodiments according to the invention are explained in conjunction with drawings.

### First Embodiment

### Constitution of Railway Vehicle

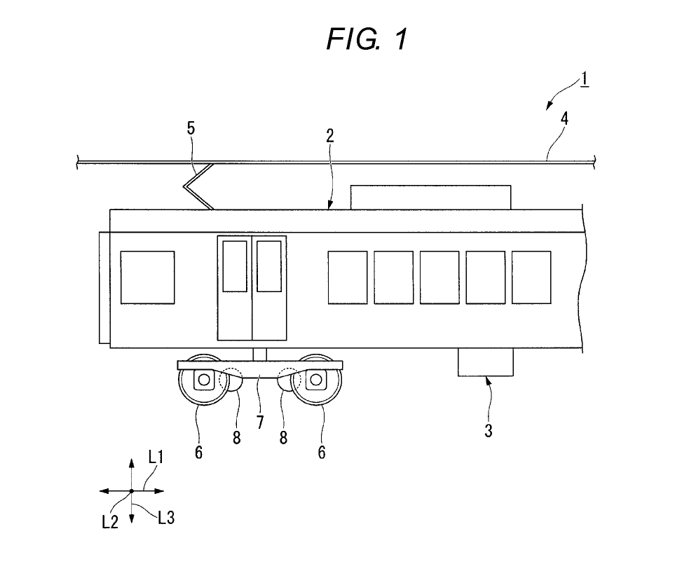

As shown in FIG. 1, a railway vehicle 1 of this embodiment includes a vehicle body 2 and an electric power conversion device 3 mounted on an underfloor of the vehicle body 2.

The electric power conversion device 3 is a device which converts a DC power supplied from an overhead line 4 through a pantograph 5, or a DC power supplied from a power supply source not shown in the drawing into an AC power, and supplies the AC power to main electric motors 8 which are mounted on a chassis 7 where left and right wheels 6 are pivotally supported and respective electrical equipment (air conditioner and the like) not shown in the drawing in the railway vehicle 1, for example. The wheels 6 travel on rails arranged on a ground not shown in the drawing.

In this embodiment, the direction which connects a front side and a rear side of the vehicle body 2 is referred to as “longitudinal direction L1”, the vehicle width direction of the vehicle body 2 is referred to as “lateral direction L2”, and the height direction of the vehicle body 2 is referred to as “vertical direction L3”.

### [Constitution of Electric Power Conversion Device for Vehicle]

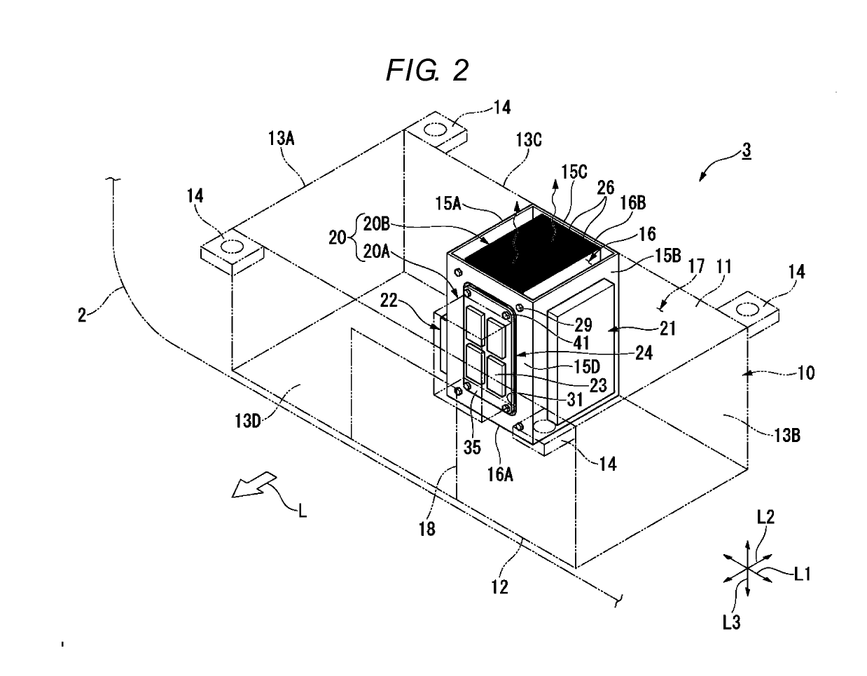

As shown in FIG. 2, the electric power conversion device 3 includes: a box body (control box) 10 mounted on the underfloor of the vehicle body 2, a power unit 20 accommodated in the inside of the box body 10; a filter capacitor 21; and a gate amplifier 22.

### (Box Body)

The box body 10 includes a ceiling wall portion 11 which faces an underfloor of the vehicle body 2, a bottom wall portion 12 which faces a railway (rails not shown in the drawing), and four side wall portions 13A, 13B directed in the longitudinal direction L1, and 13C, 13D directed in the lateral direction L2. The box body 10 made of metal having a rectangular parallelepiped shape is formed by these respective wall portions (the ceiling wall portion 11, the bottom wall portion 12, and the side wall portions 13A to 13D).

The box body 10 is mounted on the underfloor of the vehicle body 2 in a suspended manner by way of a plurality of mounting members 14 mounted on the ceiling wall portion 11. To be more specific, when the railway vehicle 1 is viewed from a front side, the box body 10 is mounted on the underfloor of the vehicle body 2 at a position close to one (left or right) side of the vehicle body 2 such that the box body 10 falls within an outfitting limit (predefined design constraint for size) not shown in the drawing. In this example, the one side is assumed to be the left.

The mounting members 14 are formed such that the mounting members 14 project outward in the lateral direction L2 from four corners of the ceiling wall portion 11. A mounting position of the box body 10, the number of mounting members 14 and the like are not limited to the above-mentioned case, and the mounting position of the box body 10, the number of mounting members 14 and the like may be changed when necessary.

The box body 10 is partitioned into a cooling air chamber 16 and a mounting chamber 17 by four partition plates 15A to 15D which extend in the vertical direction L3.

The partition plates 15A, 15B are directed in the longitudinal direction L1, and face the side wall portions 13A, 13B of the box body 10 in an opposed manner with a space defined therebetween respectively. The partition plate 15C is in contact with the side wall portion 13C of the box body 10. The partition plate 15D is directed to a vehicle left side L, and faces the side wall portion 13D of the box body 10 in an opposed manner with a space therebetween.

An inner space surrounded by these four partition plates 15A to 15D forms the cooling air chamber 16. Accordingly, in the example shown in the drawing, the cooling air chamber 16 is arranged at the center portion of the box body 10 in the longitudinal direction L1 and at the position close to the center of the vehicle body 2 in the vehicle width direction. The cooling air chamber 16 is configured such that the cooling air chamber 16 pierces through the box body 10 in the vertical direction L3. The position of the cooling air chamber 16 is not limited to the above-mentioned position.

The cooling air chamber 16 is configured such that the cooling air chamber 16 pierces through the box body 10 in the vertical direction L3 and hence, the cooling air chamber 16 opens to the ceiling wall portion 11 and the bottom wall portion 12 respectively. Out of the portions where the cooling air chamber 16 has openings, the portion which of the chamber open to the bottom wall portion 12 forms an air chamber opening 16A, and the portion of the chamber open to the ceiling wall portion 11 forms an air chamber opening 16B. A heat radiation part 20B of the power unit 20 is accommodated within the cooling air chamber 16.

A part of the inside of the box body 10 other than the cooling air chamber 16 forms the mounting chamber 17. A heat generation part 20A of the power unit 20 is accommodated within the mounting chamber 17. The filter capacitor 21, the gate amplifier 22 and other various electric power conversion equipment not shown in the drawing are also accommodated within the mounting chamber 17.

In the side wall portion 13D of the box body 10 which is located to the vehicle left side L of the vehicle body 2, an opening portion 18 is formed, through which the heat generation part 20A accommodated within the mounting chamber 17 is introduced into, or removed from, the mounting chamber 17. Usually, the opening portion 18 is closed by a cover (not shown in the drawing).

### (Power Unit)

As shown in FIG. 2 to FIG. 4, the power unit 20 includes a heat generation part 20A, a heat radiation part 20B, and a heat transferring sheet 24. The heat generation part 20A is arranged in the inside of the mounting chamber 17 and includes a semiconductor element 23 for performing power conversion. The heat radiation part 20B is attached to the partition plate 15D inside the cooling air chamber 16 and radiates heat generated at the heat generation part 20A. The heat transfer sheet 24 is provided between the heat generation part 20A and the heat radiation part 20B.

### (Heat Removing Part)

The heat radiation part 20B is explained in detail.

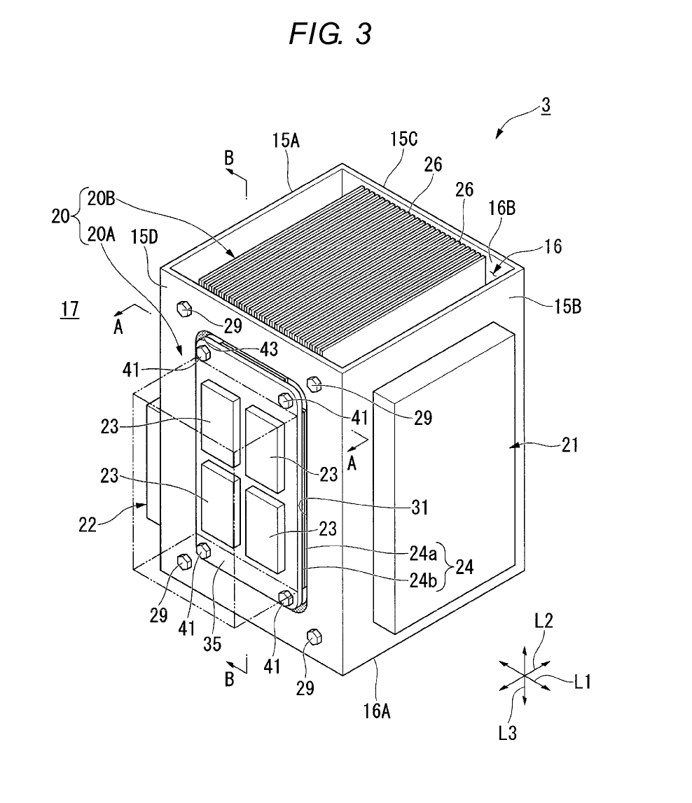

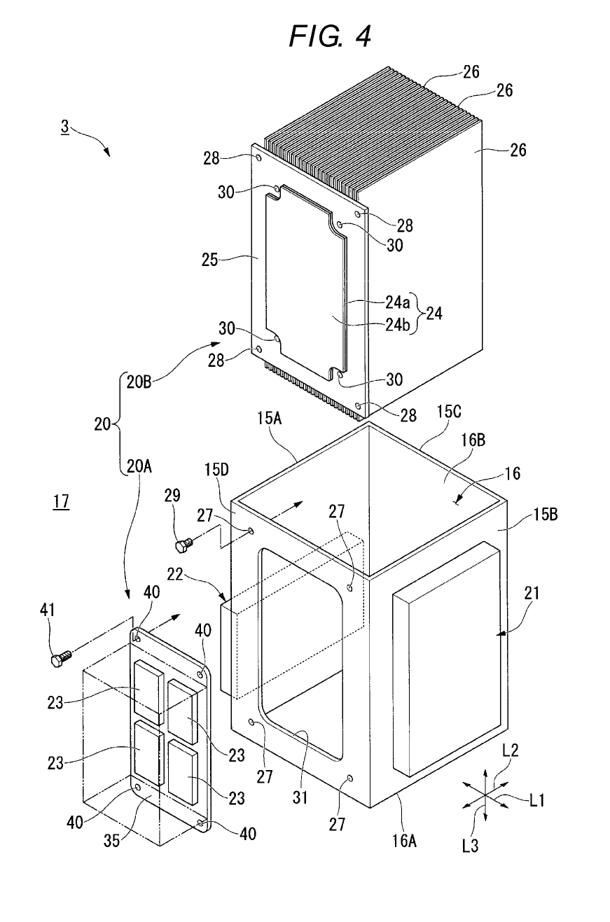

As shown in FIG. 3 and FIG. 4, the heat radiation part 20B includes a heat radiation plate 25 and a plurality of cooling fins 26 which are integrally formed on the heat radiation plate 25.

The heat radiation plate 25 is made of a metal material having excellent thermal conductivity (aluminum or the like, for example), and is formed in a rectangular shape which is elongated more in the vertical direction L3 than in the longitudinal direction L1 as viewed in the side view. First threaded holes 28 are formed in the heat radiation plate 25 at around four corners of the heat radiation plate 25 respectively such that the first threaded holes 28 correspond to four first bolt through holes 27 formed in the partition plate 15D. The heat radiation plate 25 is made to overlap with the partition plate 15D from a side of a cooling air chamber 16, and is fixed to the partition plate 15D by first fixing screws (bolts) 29 which are threadedly engaged with the first threaded holes 28 through the first bolt through holes 27.

Four second threaded holes 30 for affixing the heat generation part 20A to the heat radiation plate 25 are formed in the heat radiation plate 25 at portions positioned more inside of (more toward the center of) the heat radiation plate 25 than four first threaded holes 28.

The cooling fins 26 are plate-shaped fins which are made of a metal material having excellent thermal conductivity (aluminum or the like, for example), and are arranged along the vertical direction L3 (along the direction from the air chamber opening 16A to the air chamber opening 16B of the cooling air chamber 16). Each cooling fin 26 has a length which extends to the air chamber opening 16B from the air chamber opening 16A. These cooling fins 26 are arranged parallel to each other in the longitudinal direction L1 with a gap therebetween.

The plurality of cooling fins 26 may be integrally mounted on the heat radiation plate 25 by thermally conductive caulking, brazing or the like, or may be integrally mounted on the heat radiation plate 25 by other methods.

### (Heat Generation Part)

The heat generation part 20A is detachably mounted on the heat radiation part 20B in a state where the heat generation part 20A is arranged on a side opposite to the heat radiation part 20B with the partition plate 15D sandwiched therebetween. In the example shown in the drawing, the heat generation part 20A is directly mounted on the heat radiation part 20B through a mounting opening portion 31 formed in the partition plate 15D while sandwiching the heat transfer sheet 24 between the heat generation part 20A and the heat radiation part 20B.

Detailed explanation will now be given.

As shown in FIG. 3 to FIG. 6, the heat generation part 20A is a unit which includes a heat receiving plate (power unit block) 35, a plurality of the semiconductor elements 23, a conductor 36, two smoothing capacitors 37, and a gate substrate 38. The plurality of the semiconductor elements 23 are mounted on the heat receiving plate 35. The conductor 36 is made to overlap with the plurality of semiconductor elements 23 for forming a predetermined power conversion circuit pattern when the conductor 36 is made conductive with terminal portions (not shown in the drawing) of the respective semiconductor elements 23. The two smoothing capacitors 37 are made to overlap with the conductor 36. The gate substrate 38 is made to further overlap with these smoothing capacitors 37.

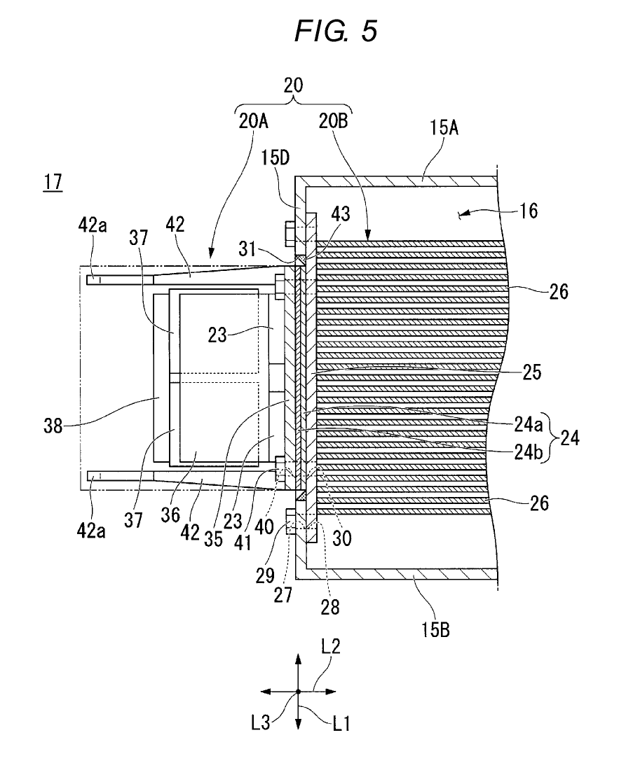

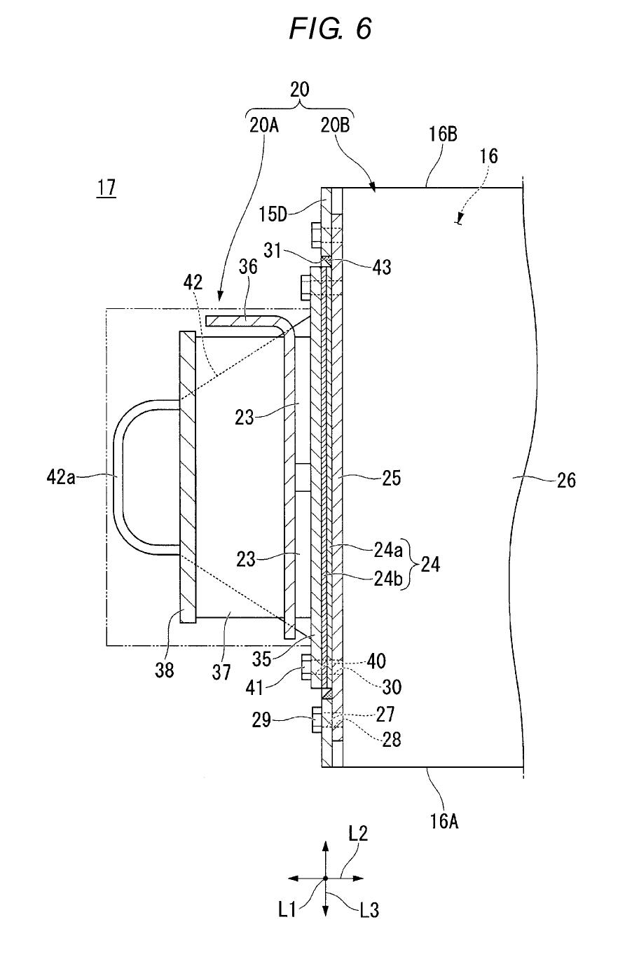

In the respective drawings other than FIG. 5 and FIG. 6, the heat generation part 20A is illustrated in a simplified manner.

In the same manner as the heat radiation plate 25, the heat receiving plate 35 is a generally flat plate which is made of a metal material having excellent thermal conductivity (aluminum or the like, for example), and is formed in a rectangular shape which elongated more in the vertical direction L3 than in the longitudinal direction L1 as viewed in a side view. Second through bolt holes 40 are formed in the heat receiving plate 35 at the four corners of the heat receiving plate 35 respectively such that the second bolt through holes 40 correspond to the four second threaded holes 30 formed in the heat receiving plate 35.

The heat receiving plate 35 is made to overlap with the heat radiation plate 25 from a side of a mounting chamber 17 with the heat transfer sheet 24 sandwiched between the heat receiving plate 35 and the heat radiation plate 25 through the mounting opening portion 31 formed in the partition plate 15D, and is directly fixed to the heat radiation plate 25 by second fixing screws (bolts) 41 threadedly engaged with the second threaded holes 30 through the second bolt through holes 40.

The semiconductor elements 23 contained in the heat generation part 20A perform power conversion by switching on and off in response to turn-on/turn-off signals from the gate amplifier 22.

In the example shown in the drawing, four semiconductor elements 23 are mounted on the heat receiving plate 35 in total such that the two semiconductor elements 23 are arranged in a spaced-apart manner in the longitudinal direction L1 and the two semiconductor elements 23 are also arranged in a spaced-apart manner in the vertical direction L3. The number of the semiconductor elements 23 is not limited to the number adopted in the above-mentioned case. Components other than the semiconductor elements 23 are not limited to those adopted in the above-mentioned case, and other parts may be incorporated when necessary.

The heat generation part 20A of the power unit 20, since the semiconductor elements 23 generate heat attributed to a power loss at the time of power conversion by the above-mentioned switching, has a tendency that a temperature of the heat generation part 20A becomes higher than temperatures of the gate amplifier 22 and the filter capacitor 21 which are accommodated in the inside of the mounting chamber 17. Accordingly, the radiation of heat generated from the heat generation part 20A of the power unit 20 is more predominant than the radiation of heat generated from the gate amplifier 22 or the filter capacitor 21.

A pair of frame plates 42 are mounted on the heat receiving plate 35 at portions thereof positioned to the sides of the semiconductor elements 23 in the longitudinal direction L1. The pair of frame plates 42 are formed in a trapezoidal shape as viewed in a side view, and each is formed on the heat receiving plate 35 in an extended manner with the semiconductor elements 23 located therebetween. A handle 42a is mounted on a top portion of each of the pair of frame plates 42. Due to such a constitution, the heat generation part 20A may be mounted easily or removed easily from the heat radiation plate 25, or may be easily carried by using the handles 42a.

The mounting opening portion 31 formed in the partition plate 15D has a rectangular shape as viewed in a side view, and a size of the mounting opening portion 31 is sized to be larger than an size of the heat receiving plate 35 and is sized to be smaller than the size of the heat radiation plate 25. Accordingly, the heat generation part 20A may be directly fixed to the heat radiation part 20B by way of the heat receiving plate 35 while preventing the inside of the mounting chamber and the inside of the cooling air chamber 16 from communicating with each other through the mounting opening portion 31.

An opening periphery of the mounting opening portion 31 is sealed by a sealing material 43 over the whole circumference of the mounting opening portion 31. Accordingly, a gap formed between the opening periphery of the mounting opening portion 31 and the heat radiation plate 25 is securely sealed so that communication between the inside of the mounting chamber 17 and the inside of the cooling air chamber 16 through the mounting opening portion 31 is prevented more effectively. In FIG. 4, the illustration of the sealing material 43 is omitted.

### (Heat Transfer Sheet)

As shown in FIG. 4, the heat transfer sheet 24 is a sheet which has high thermal conductivity due to mixing of a heat conductive material (not shown in the drawing) such as metal fillers therein, and also has excellent flexibility and an excellent adhesiveness. The heat conductive material is arranged in the thickness direction in the heat transfer sheet 24, so that the thermal conductivity of the heat transfer sheet 24 in the thickness direction thereof is higher than the thermal conductivity of the heat transfer sheet 24 in the planar direction thereof, i.e., a higher thermal conductivity between the heat receiving plate 35 and the heat radiation plate 25, than between the center and perimeter edges thereof.

The heat transfer sheet 24 is formed in a rectangular shape and has substantially the same size as the heat receiving plate 35 as viewed in a side view. The heat transfer sheet 24 is brought into contact with the whole surface of the heat receiving plate 35. The heat transfer sheet 24 has a two-layered structure which is formed of a sheet body 24a and a non-adhesive layer (a layer made of aluminum, for example) 24b. The non-adhesive layer 24b is arranged against the side or generally planar face of the heat generation part 20A. The sheet body 24a has a slight adhesiveness so that the sheet body 24a may be temporarily fixed to the heat radiation plate 25 by adhesion.

In the example shown in the drawing, four corners of the heat transfer sheet 24 are notched in a circular arc shape (i.e., has arc shaped cutouts at the corners) so that contact (electrical conduction) between the non-adhesive layer 24b and the second fixing screws 41 is prevented.

### (Filter Capacitor and Gate Amplifier)

As shown in FIG. 2 and FIG. 3, the filter capacitor 21 and the gate amplifier 22 are accommodated in the inside of the mounting chamber 17 in a state where the filter capacitor 21 and the gate amplifier 22 are directly mounted on the partition plates 15A, 15B respectively by fastening means such as screws (not shown in the drawing), and are arranged parallel to each other in the longitudinal direction L1 with the cooling air chamber 16 sandwiched therebetween. The filter capacitor 21 and the gate amplifier 22 are electrically connected with the semiconductor elements 23 of the power unit 20.

Mounting positions of the filter capacitor 21 and the gate amplifier 22 are not limited to the above-mentioned positions, and may be changed suitably provided that the mounting positions are within the mounting chamber 17. Various equipment necessary for performing power conversion may be arranged in the inside of the mounting chamber 17 in addition to the above-mentioned heat generation part 20A, the filter capacitor 21 and the gate amplifier 22 of the power unit 20.

### [Manner of Operation and Advantageous Effects]

Next, the manner of operation of the electric power conversion device 3 having the above-mentioned constitution is explained.

When a DC power is supplied to the electric power conversion device 3 from the overhead line 4 or a power supply source not shown in the drawing, to prevent an inrush current to the power unit 20, the DC power is initially charged into the filter capacitor 21 shown in FIG. 2 and, thereafter, is supplied to the semiconductor elements 23 of the power unit 20. When the DC power is supplied to the semiconductor elements 23, the semiconductor elements 23 performs switching in response to the turn-on/turn-off signals from the gate amplifier 22 thus performs the power conversion from a DC power into an AC power. Accordingly, power necessary for moving of the railway vehicle 1 is ensured.

Heat generated from the semiconductor elements 23 at the time of performing the power conversion may be sequentially transferred to the heat radiation part 20B arranged in the inside of the cooling air chamber 16, in the order of the heat receiving plate 35, the heat transfer sheet 24, the heat radiation plate 25 and the cooling fins 26, and the heat radiation part 20B radiates, by radiative, convective and conductive heat transfer of the heat into the adjacent air environment in the cooling air chamber 16. Due to such radiation of heat into the air in the cooling chamber, outside air in the cooling air chamber 16 is warmed so that a natural convection which flows toward the air chamber opening 16B from the air chamber opening 16A is induced in the cooling air chamber 16.

Accordingly, heat transferred from the heat generation part 20A may be transferred to outside air which constantly flows into the inside of the cooling air chamber 16 through the air chamber opening 16A, and the heat generation part 20A may be cooled due to a heat exchange performed by the radiation, convection and conduction of heat into this air stream. In such transfer of heat, the heat radiation part 20B includes the plurality of cooling fins 26 and hence, the heat exchange between heat and outside air which flows in the cooling air chamber 16 may be smoothly performed. Accordingly, heat transfer performance is enhanced and hence, the heat generation part 20A may be rapidly cooled.

Particularly, the heat transfer sheet 24 is provided between the heat generation part 20A and the heat radiation part 20B and hence, heat generated from the semiconductor elements 23 of the heat generation part 20A may be efficiently transferred to the heat radiation part 20B with little thermal resistance. Further, the heat transfer sheet 24 is sandwiched between the heat receiving plate 35 and the heat radiation plate and hence, any extremely small surface unevenness, deflection portions or the like of the heat receiving plate 35 and the heat radiation plate 25 may be absorbed by making use of flexibility (elasticity) of the heat transfer sheet 24. Accordingly, the heat transfer sheet 24 is brought into close, intimate, contact with the heat receiving plate 35 and the heat radiation plate 25 without forming a gap therebetween. Due to such a constitution, heat may be transferred to the heat radiation part 20B from the heat generation part 20A with extremely high efficiency. Accordingly, excellent cooling performance may be exhibited and hence, it is possible to prevent the temperature elevation in the heat generation part 20A and the temperature elevation in the mounting chamber 17.

The heat transfer sheet 24 is sandwiched between the heat receiving plate 35 and the heat radiation plate 25 and is brought into close contact with both plates and hence, the heat receiving plate 35 may be mounted on the heat radiation plate 25 with a small play in an extremely stable manner. Accordingly, the heat generation part 20A may be fixed to the heat receiving plate 35 in a sufficiently stable manner by making use of the four second fixing screws 41 arranged at four corners of the heat receiving plate 35 respectively.

In this embodiment, the heat receiving plate 35 is directly mounted on the heat radiation plate 25 with the heat transfer sheet 24 sandwiched therebetween, and the thermal conductivity of the heat transfer sheet 24 in the thickness direction is configured to be larger than the thermal conductivity of the heat transfer sheet 24 in the planar direction. Due to such a constitution, heat generated from the heat generation part 20A may be transferred to the heat radiation part 20B more efficiently and hence, the high cooling performance may be expected.

The heat generation part 20A and the heat radiation part 20B are arranged in the inside of the mounting chamber 17 and the cooling air chamber 16 which are partitioned by the partition plate 15D respectively. Accordingly, a hermetically sealed state may be formed in the inside of the mounting chamber 17 with a structure which uses no packings. Accordingly, the whole constitution of the electric power conversion device 3 may be simplified due to the structure which uses no packings while enhancing the waterproof property of the arrangement.

The heat generation part 20A is detachably mounted on the heat radiation part 20B which is mounted on the partition plate 15D by making use of the second fixing screws 41. Accordingly, only the heat generation part 20A need be mounted or removed while leaving the heat radiation part 20B as is, and the heat generation part 20A may be introduced into or removed from the box body 10 through the opening portion 18. Accordingly, it is possible to enhance the ease of mounting or removing the heat generation part 20A so that, for example, a maintenance operation of the heat generation part 20A or the like may be smoothly performed.

Further, the power unit 20 adopts the structure where the heat generation part 20A and the heat radiation part 20B are separable from each other and hence, the heat generation part 20A and the heat radiation part 20B may be designed individually whereby the constitution of the power unit 20 may be simplified and miniaturized.

Since the heat transfer sheet 24 includes the non-adhesive layer 24b, in removing the heat generation part 20A, the heat transfer sheet 24 and the heat receiving plate 35 may be easily separated from each other. Accordingly, the operability of mounting or removing the heat generation part 20A may be further enhanced. Further, for example, peeling off or breaking or the like of the heat transfer sheet 24 is scarcely generated when the heat generation part 20A is mounted or removed and hence, the heat transfer sheet 24 may be used without being replaced more than necessary.

As has been explained above, according to this embodiment, heat generated from the heat generation part 20A of the power unit 20 may be efficiently transferred to the heat radiation part 20B and hence, excellent cooling performance may be realized. Accordingly, the temperature elevation in the heat generation part 20A and the temperature elevation in the mounting chamber 17 may be effectively prevented and, at the same time, the operability of mounting or removing the heat generation part 20A may be also enhanced.

Since the railway vehicle 1 includes the electric power conversion device 3 having the constitution as described above, power supply can be stabilized and accordingly the railway vehicle 1 can realize excellent traveling performance.

### Modification of First Embodiment

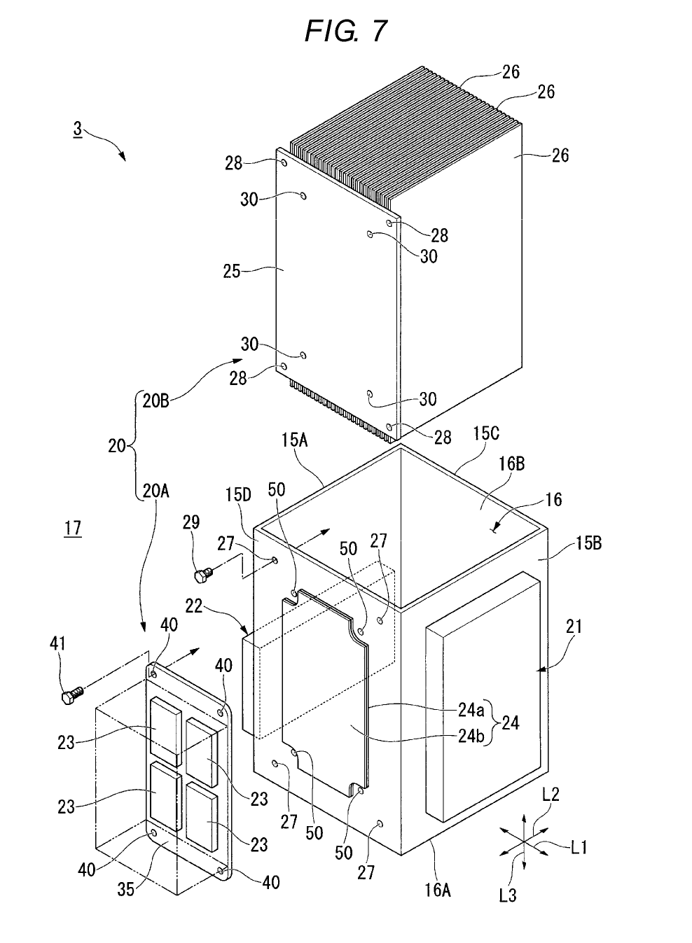

In the first embodiment described above, the heat generation part 20A is directly mounted on the heat radiation part 20B through the mounting opening portion 31 formed in the partition plate 15D in a state where the heat transfer sheet 24 is sandwiched between the heat generation part 20A and the heat radiation part 20B. However, the mounting of the heat generation part 20A is not limited to such a mode. For example, as shown in FIG. 7, the heat generation part 20A may be mounted to the heat radiation part 20B, but with the partition plate 15D sandwiched therebetween, i.e., without forming the mounting opening portion 31 in the partition plate 15D.

In this case, the heat transfer sheet 24 is not arranged on the heat radiation plate 25 but it is arranged on a side of a heat generation part 20A of the partition plate 15D such that the heat transfer sheet 24 is sandwiched between the heat receiving plate 35 of the heat generation part 20A and the partition plate 15D. Third bolt through holes 50 are formed in the partition plate 15D at positions corresponding to the second threaded holes 30 formed in the heat radiation plate 25.

Further, the heat receiving plate 35 is made to overlap with the partition plate 15D from a side of a mounting chamber 17 in a state where the heat transfer sheet 24 is sandwiched between the partition plate 15D and the heat generation part 20A, and is fixed to the heat radiation part 20B by the second fixing screws 41 threadedly engaged with the second threaded holes 30 through the second bolt through holes 40 and the third bolt through holes 50 with the partition plate 15D sandwiched therebetween.

Even with the electric power conversion device 3 having the above-mentioned constitution, heat generated from the semiconductor elements 23 may be transferred to a side of the heat radiation part 20B in the order of the heat receiving plate 35, the heat transfer sheet 24, the partition plate 15D and the heat radiation plate 25 and hence, the electric power conversion device 3 according to this modification may acquire the manner of operation and advantageous effects substantially equal to those of the above-mentioned first embodiment.

Particularly, in this modification, heat transferred to the partition plate 15D may be transferred not only to the heat radiation plate 25 but also to a greater extent to the remaining partition plates 15A to 15C so that heat may be radiated by making use of whole area of the partition plates 15A to 15D whereby a greater cooling capacity may be expected.

In the first embodiment, however, heat can be directly transferred to the heat radiation plate 25 from the heat receiving plate 35 by way of the heat transfer sheet 24. Accordingly, the first embodiment is more preferable.

### Second Embodiment

Next, an electric power conversion device for a vehicle of the second embodiment is explained.

The constitution which makes this embodiment different from the first embodiment is as follows. In the first embodiment, the cooling air chamber 16 is arranged such that the cooling air chamber 16 penetrates the box body 10 in the vertical direction L3 using the partition plate 15D. In the second embodiment, the cooling air chamber 16 is arranged such that the cooling air chamber 16 penetrates the box body 10 in the longitudinal direction L1.

In the second embodiment, constitutional elements identical with the constitutional elements of the first embodiment are given same symbols, and the explanation of these elements is omitted.

### [Constitution of Electric Power Conversion Device for Vehicle]

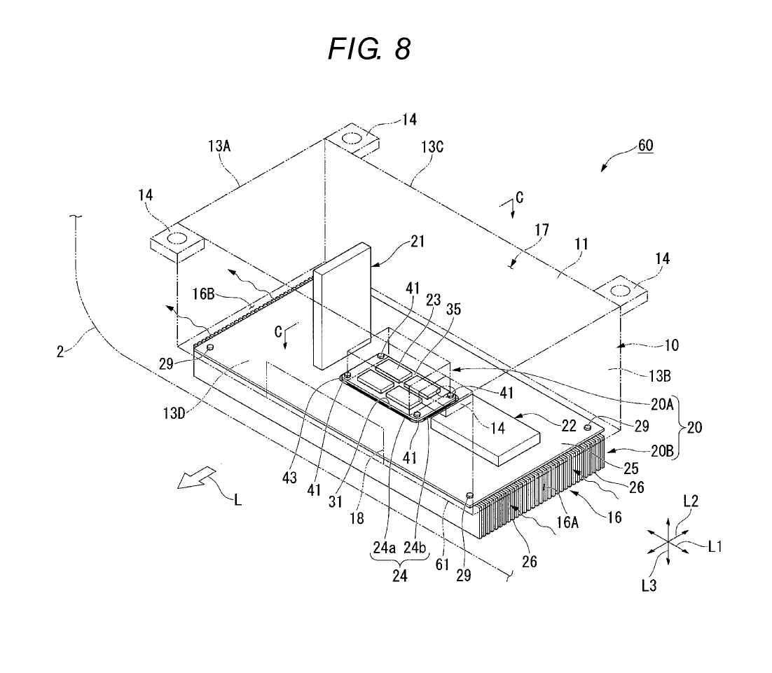

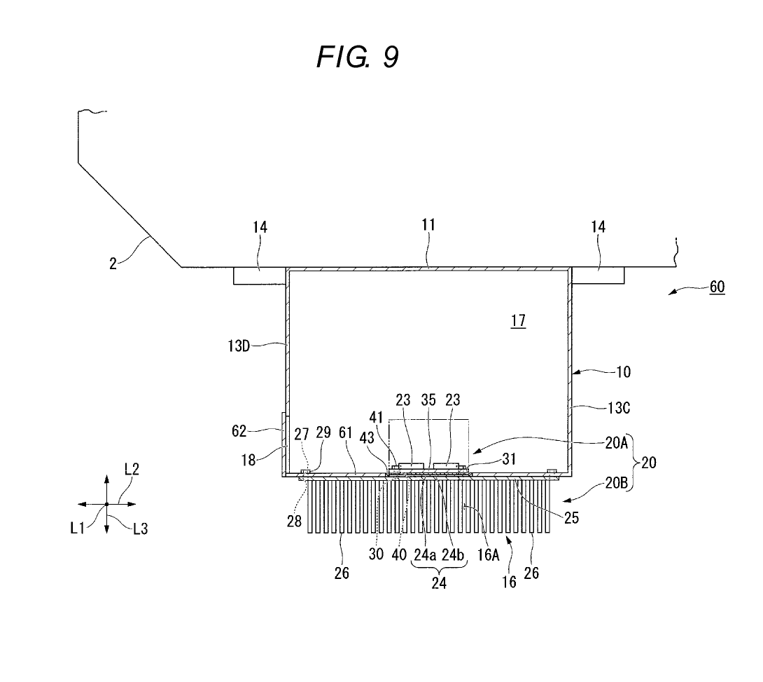

As shown in FIG. 8 and FIG. 9, in an electric power conversion device 60 of this embodiment, a bottom wall portion 61 of the box body 10 constitutes a partition plate, and the cooling air chamber 16 and the mounting chamber 17 are vertically partitioned by the bottom wall portion 61. Accordingly, the cooling air chamber 16 of this embodiment is of an external air chamber type (an open volume of air below the mounting chamber) where the cooling air chamber 16 is arranged below the mounting chamber 17.

The air chamber opening 16A faces one side of the vehicle body 2, and the air chamber opening 16B faces another side of the vehicle body 2. Accordingly, the cooling air chamber 16 is formed such that the air chamber opening 16B and the air chamber opening 16A are arranged parallel to each other in the longitudinal direction L1.

The example shown by FIG. 8 and FIG. 9, the cooling air chamber 16 is exposed. However, except for the air chamber opening 16A and the air chamber opening 16B, the cooling air chamber 16 can be covered by a cover material.

The power unit 20 differs from the power unit 20 of the first embodiment only with respect to the following constitution. That is, the power unit 20 of this embodiment is mounted on the bottom wall portion 61 while the power unit 20 of the first embodiment is mounted on the partition plate 15D. Accordingly, the power unit 20 is explained simply.

As shown in FIG. 9, the heat radiation part 20B of the power unit 20 is mounted on the bottom wall portion 61 from a side of a cooling air chamber 16 (lower side) by the first fixing screws 29. The heat generation part 20A of the power unit 20 is made to overlap with the heat radiation plate 25 from a side of a mounting chamber 17 (upper side) through the mounting opening portion 31 formed in the bottom wall portion 61 with the heat transfer sheet 24 sandwiched therebetween, and the heat generation part 20A is directly fixed to the heat radiation plate 25 by the second fixing screws 41.

The filter capacitor 21 and the gate amplifier 22 are placed in the mounting chamber 17 in a state where the filter capacitor 21 and the gate amplifier 22 are also directly mounted on the bottom wall portion 61 respectively by fastening means such as screws not shown in the drawing. The mounting of the filter capacitor 21 and the gate amplifier 22 are not limited to such a mode, and these parts may be mounted at any position provided that these parts are mounted within the mounting chamber 17.

The opening portion 18 formed in the box body 10 is formed at a position where the heat generation part 20A may be introduced into or removed from the box body 10 through the opening portion 18 while moving the heat generation part 20A along the bottom wall portion 61. A size of the opening portion 18 is set to a size which corresponds to a side surface of the heat generation part 20A whose cross-sectional area is smaller than an upper surface of the heat generation part 20A. Usually, the opening portion 18 is closed by a cover 62.

### [Manner of Operation and Advantageous Effects]

The electric power conversion device for a vehicle 60 of this embodiment may acquire the following manner of operation and advantageous effects in addition to the manner of operation and advantageous effects substantially equal to the manner of operation and the advantageous effects of the first embodiment.

The cooling air chamber 16 is arranged along the longitudinal direction L1 and hence, air passing under the vehicle during vehicle movement may be taken into the inside of the cooling air chamber 16 during traveling of the railway vehicle 1. Accordingly, outside air whose temperature is increased due to a heat exchange with cooling fins 26 may be rapidly discharged from the cooling air chamber 16 and, further, a large amount of outside air is taken into the inside of the cooling air chamber 16 and hence, it is possible to positively accelerate the heat transfer from the heat generation part 20A. Due to such a constitution, cooling performance may be further enhanced.

To remove and replace the heat generation part 20A, the heat generation part 20A may be pulled out from the box body 10 through the opening portion 18 in the side of the box body 10 by moving the heat generation part 20A such that the heat generation part 20A slides on the bottom wall portion 61, for example, and hence, it is unnecessary to raise the heat generation part 20A. Due to such a constitution, for example, even when the heat generation part 20A is large and heavy, the heat generation part 20A may be easily removed so that a burden imposed on an operator may be reduced. Accordingly, the operability of mounting or removing the heat generation part 20A may be further enhanced.

Further, the opening portion 18 is formed in the side wall portion 13D which faces the vehicle left side L and hence, a mounting and removing operation of the heat generation part 20A may be performed extremely easily. Further, the heat generation part 20A may be pulled out in a state where a side of a side surface which has small cross-sectional area is set on a viewer's side and hence, a size (width) of the opening portion 18 may be set smaller compared to the opening portion 18 of the first embodiment.

### Third Embodiment

Next, an electric power conversion device for a vehicle of the third embodiment according to the invention is explained.

The constitution which makes this embodiment different from the second embodiment is as follows. In the second embodiment, relative air movement between the cooling air chamber and the ambient surroundings caused by movement of the train vehicle air flow caused by movement causes air to pass through the inside of the cooling air chamber 16 (through the exposed fins of the heat exchanger extending below the box body 10). In the third embodiment, outside air is forcibly taken into the cooling air chamber 16 by making use of a fan.

In the third embodiment, constitutional elements identical with the constitutional elements of the second embodiment are given same symbols, and the explanation of these constitutional parts is omitted.

### [Constitution of Electric Power Conversion Device for Vehicle]

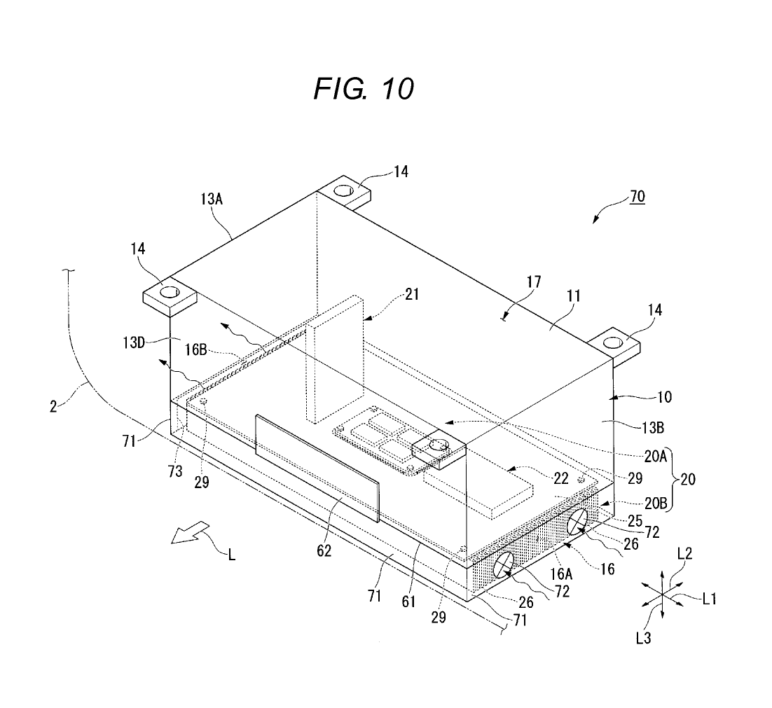

As shown in FIG. 10, in an electric power conversion device 70 of this embodiment, the box body 10 includes an air chamber wall portion 71 which surrounds the periphery of the cooling fins 26, and an inner space surrounded by the air chamber wall portion 71 and the bottom wall portion 61 constitutes the cooling air chamber 16. Fans 72 which take outside air into the inside of the cooling air chamber 16 are arranged at portions of the air chamber wall portion 71 which are positioned at the air chamber opening 16A. In the example shown in the drawing, the two fans 72 are arranged in a spaced-apart manner in the lateral direction L2. A discharge opening 73 for discharging the outside air from the cooling air chamber 16 therethrough is formed in a portion of the air chamber wall portion 71 which is positioned at the air chamber opening 16B.

### [Manner of Operation and Advantageous Effect]

According to the electric power conversion device 70 of this embodiment, a fixed amount of outside air may be forcibly taken into the inside of the cooling air chamber 16 by operating the fans 72 and hence, heat may be radiated in a stable manner while preventing the stagnation of outside air. Particularly, forced-air cooling is adopted and hence, cooling is not significantly influenced by the speed of the railway vehicle 1, and cooling may be performed by taking outside air into the inside of the cooling air chamber 16 even when the railway vehicle 1 is in a stopped state. Accordingly, stable cooling performance may be ensured.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the respective embodiments, the heat transfer sheet which exhibits higher thermal conductivity in the thickness direction than the planar direction and has the two-layered structure which includes a non-adhesive layer is adopted. However, the heat transfer sheet is not limited to the such a heat transfer sheet. The heat transfer sheet may not include the non-adhesive layer, or the direction of the thermal conductivity may not be the thickness direction. In any case, it is sufficient for the heat transfer sheet that the heat transfer sheet may transfer heat generated from a heat generation part to a heat radiation part.

What is claimed is:

1. An electric power conversion device for a vehicle comprising:
a box body partitioned into a cooling air chamber and a mounting chamber;
a heat generation part which is arranged in the inside of the mounting chamber and includes a semiconductor element which performs power conversion; and
a heat radiation part mounted on a partition between the cooling air chamber and mounting chamber, and configured to radiate heat generated from the heat radiation part, wherein
the heat generation part is detachably mounted on the heat radiation part in a state where the heat generation part is arranged on a side opposite to the heat radiation part with the partition sandwiched therebetween, and
a heat transfer sheet is provided between the heat generation part and the heat removing part.

2. The electric power conversion device according to claim 1, wherein
the heat generation part is directly mounted on the heat radiation part through a mounting opening portion formed in the partition while sandwiching the heat transfer sheet between the heat generation part and the heat radiation part.

3. The electric power conversion device according to claim 1, wherein
the heat transfer sheet has higher thermal conductivity in the thickness direction than in the planar direction thereof.

4. The electric power conversion device according to claim 1, wherein
the heat transfer sheet includes a non-adhesive layer on a side of the heat generation part.

5. The electric power conversion device according to claim 1, wherein
the partition is a bottom wall portion of the box body which partitions the cooling air chamber and the mounting chamber, and
an opening portion through which the heat generation part is introduced into or removed from the box body is formed on a side wall portion of the box body.

6. The electric power conversion device according of claim 1, wherein
the heat radiation part includes a plurality of cooling fins, and
the cooling fins are arranged along a direction which is directed from an air chamber inlet of the cooling air chamber to an air chamber outlet of the cooling air chamber such that air flowing from the inlet to the outlet may pass between adjacent fins without interruption of the flow.

7. The electric power conversion device according to claim 6, wherein
the box body is arranged such that the air chamber inlet and the air chamber outlet are spaced apart along the longitudinal direction of the vehicle.

8. The electric power conversion device according to claim 1, wherein
the heat radiation part includes a fan which is arranged at the air chamber inlet to force air past the heat radiation part.

9. A railway vehicle comprising:
an electric power conversion device for a vehicle that includes
a box body partitioned into a cooling air chamber and a mounting chamber by partition plates;
a heat generation part which is arranged in the inside of the mounting chamber and includes a semiconductor element which performs power conversion; and
a heat radiation part mounted on the partition plate, and configured to transfer heat generated from the heat generation part from the heat generation part, wherein
the heat generation part is detachably mounted on the heat radiation part in a state where the heat generation part is arranged on a side opposite to the heat radiation part with the partition plate sandwiched therebetween, and
a heat transfer sheet is provided between the heat generation part and the heat radiation part; and
a vehicle body to which the box body is mounted on an underfloor.

10. The railway vehicle of claim 9, wherein the heat radiation part includes a plurality of cooling fins, wherein heat generated in the heat generation part is radiated via the cooling fins.
